(19) United States
(12) Patent Application Publication
(10) Pub. No.: US 2014/0168898 A1
(43) Pub. Date: Jun. 19, 2014

(54) HEAT DISSIPATION ELEMENT AND COMMUNICATION DEVICE USING THE SAME

(71) Applicant: Sercomm Corporation, Tapei (TW)

(72) Inventors: Hai-Kang Xu, Jiangsu province (CN); Yuan-Heng Huang, Taichung City (TW)

(73) Assignee: Sercomm Corporation, Tapei (TW)

(21) Appl. No.: 13/901,649

(22) Filed: May 24, 2013

(30) Foreign Application Priority Data
Dec. 17, 2012 (CN) 201220698506.0

(51) Int. Cl. F28F 21/04; H05K 7/20

(52) U.S. Cl. CPC F28F 21/04; H05K 7/20427
USPC 361/705; 165/185

(57) ABSTRACT

The present invention relates to a heat dissipation element and a communication device using the same. The heat dissipation element comprises a ceramic powder sintered layer and a thermal conductive metal layer. The ceramic powder sintered layer has a plurality of voids. Partial material of the thermal conductive metal layer is formed in the voids of the ceramic powder sintered layer.

This application claims the benefit of People's Republic of China application Serial No. 201220698506.0, filed Dec. 17, 2012, the subject matter of which is incorporated herein by reference.

### BACKGROUND OF THE INVENTION

1. Field of the Invention

The invention relates in general to a heat dissipation element and the communication device using the same, and more particularly to a heat dissipation element formed by ceramic powders and a communication device using the same.

2. Description of the Related Art

In the telecommunication industry, the femtocell is a cellular base station and is normally used in households or small business entities. The femtocell can be connected to an operator's core network through broadband (such as digital subscriber lines (DSL), cables or optical fibers) such that 2G, LTE, 3G and WiFi can be integrated into one device.

An ordinary femtocell comprises a circuit board and a processing chip. The processing chip is disposed on the circuit board and generates heat when operating. The accumulation of the heat increases the temperature and deteriorates the efficiency of the processing chip. Therefore, how to dissipate the heat generated by the processing chip has become a prominent task for the industries.

### SUMMARY OF THE INVENTION

The invention is directed to a heat dissipation element and a communication device using the same. The heat dissipation element dissipates the heat emitted by a heating element of the communication device.

According to an embodiment of the present invention, a heat dissipation element is provided. The heat dissipation element comprises: a ceramic powder sintered layer having a plurality of voids, and a thermal conductive metal layer whose partial material is formed in the voids of the ceramic powder sintered layer.

In the said heat dissipation element, the ceramic powder sintered layer has a lower surface, and the thermal conductive metal layer fills up the voids exposed from the lower surface.

In the said heat dissipation element, the thermal conductive metal layer is formed by a ductile material.

In the said heat dissipation element, the thermal conductive metal layer is formed by copper, aluminum or a combination thereof.

In the said heat dissipation element, the thickness of the ceramic powder sintered layer is larger than the thickness of the thermal conductive metal layer.

In the said heat dissipation element, the thickness of the ceramic powder sintered layer is 5-15 times as much as the thickness of the thermal conductive metal layer.

In the said heat dissipation element, the thermal conductive metal layer has a joint surface and a polished surface disposed oppositely to each other, and the thermal conductive metal layer is jointed to the ceramic powder sintered layer by the joint surface and is disposed on a thermal interface layer by the polished surface.

In the said heat dissipation element, the particles between the thermal conductive metal layer and the inner wall of the voids are chemically bonded to each other.

According to another embodiment of the present invention, a communication device is provided. The communication device comprises: a heating element having an upper surface, and a heat dissipation element disposed on the upper surface of the heating element. The heat dissipation element comprises a ceramic powder sintered layer having a plurality of voids, and a thermal conductive metal layer whose partial material is formed in the voids of the ceramic powder sintered layer.

In the said communication device, the heating element relates to a communication chip.

In the said communication device, the ceramic powder sintered layer has a lower surface, and the thermal conductive metal layer fills up the voids exposed from the lower surface.

The said communication device further comprises: a thermal interface layer formed between the heating element and the thermal conductive metal layer.

In the said communication device, the thermal interface layer relates to a thermal conductive double-sided adhesive, a phase changed layer or a thermal conductive pad.

In the said communication device, the thermal conductive metal layer has a joint surface and a polished surface disposed oppositely to each other, and the thermal conductive metal layer is jointed to the ceramic powder sintered layer by the joint surface and is disposed on thermal interface layer by the polished surface.

In the said communication device, the area of the heat dissipation element is at least two times as much as the area of the heating element.

The said communication device further comprises: a circuit board on which the heating element is disposed.

In the said communication device, the particles between the thermal conductive metal layer and the inner wall of the voids are bonded particles.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 shows an appearance diagram of a communication device according to an embodiment of the invention;

FIG. 2A shows an appearance diagram of a circuit board, a heating element and a heat dissipation element of FIG. 1;

FIG. 2B shows a cross-sectional view along a direction 2B-2B′ of FIG. 2A.

### DETAILED DESCRIPTION OF THE INVENTION

The principles and detailed descriptions of the present invention will be more apparent from the following detailed description taken in conjunction with the accompanying drawings.

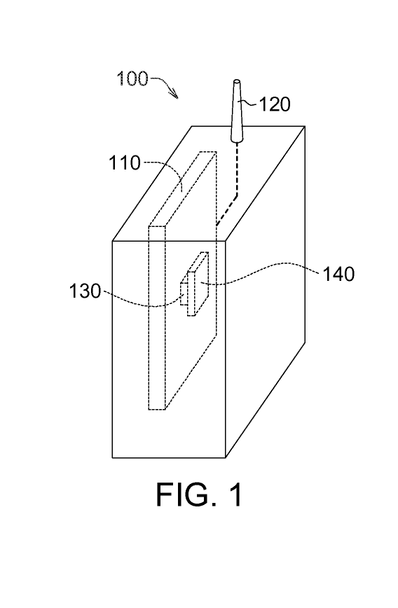

Referring to FIG. 1, an appearance diagram of a communication device according to an embodiment of the invention is shown. The communication device 100 relates to a femtocell, an IP-cam, a WiFi product, a long term evolution (LTE) application product, an integrated access device (IAD) or an optical fiber product which can be realized by such as a gigabit-capable PON (GPON) or an ethernet passive optical network (EPON). In one example, the scope of the communication device 100 may exclude devices having communication function such as desktop, notebook computers or cellular phones.

The communication device 100 comprises a circuit board 110, an antenna 120, a heating element 130 and a heat dissipation element 140. The circuit board 110 is electrically connected to the antenna 120. The antenna 120 is used for receiving or transmitting wireless signals.

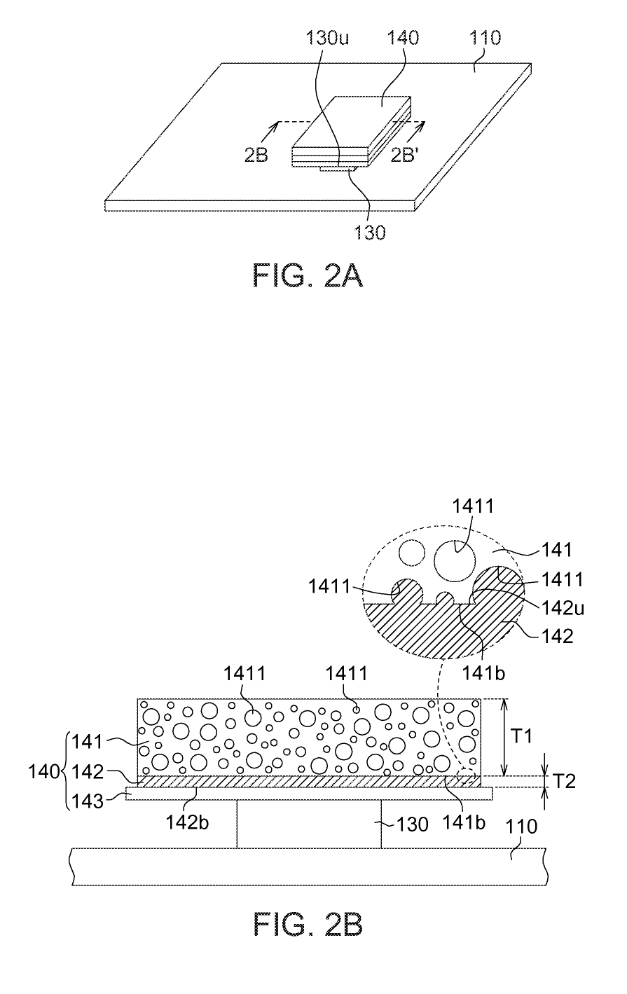

Referring to FIG. 2A, an appearance diagram of a circuit board, a heating element and a heat dissipation element of FIG. 1 is shown. The heating element 130 has an upper surface 130u. The heat dissipation element 140 is disposed on the upper surface 130u of the heating element 130 for dissipating the heat generated by the heating element 130 to the exterior.

The heating element 130 relates to a communication chip or other suitable chips. The communication chip can process wireless signals transmitted to or outputted from the antenna 120. The area of the heat dissipation element 140 (viewed along a top-view direction) is larger than the area of the heating element 130 (viewed along a top-view direction) such that dissipation efficiency can be increased. For example, the area of the heat dissipation element 140 can be larger than or equal to at least two times as much as the area of the heating element 130.

Referring to FIG. 2B, a cross-sectional view along a direction 2B-2B′ of FIG. 2A is shown. The heat dissipation element 140 comprises a ceramic powder sintered layer 141 and a thermal conductive metal layer 142. The ceramic powder sintered layer 141 can be formed by using the powder metallurgy method, and has a plurality of voids 1411 formed thereon. The design of the voids 1411 increases the surface area of the ceramic powder sintered layer 141 for dissipating the heat, and accordingly increases the dissipation efficiency of the ceramic powder sintered layer 141.

The materials of the ceramic powder sintered layer 141 comprise at least an oxide such as aluminum oxide or other suitable materials.

The thickness T1 of the ceramic powder sintered layer 141 is larger than the thickness T2 of the thermal conductive metal layer 142. For example, the thickness T1 of the ceramic powder sintered layer 141 is 5-15 times as much as the thickness T2 of the thermal conductive metal layer 142, such that the dissipation efficiency of the ceramic powder sintered layer 141 is improved or optimized.

The thermal conductive metal layer 142 has a joint surface 142u by which the thermal conductive metal layer 142 is jointed to the ceramic powder sintered layer 141. Due to the thermal conductivity of the thermal conductive metal layer 142, the heat emitted by the heating element 130 can be quickly transferred to the ceramic powder sintered layer 141, which then transfers or dissipates the heat to the exterior of the heat dissipation element 140.

The ceramic powder sintered layer 141 has a lower surface 141b from which some voids 1411 are exposed. During the process of forming the thermal conductive metal layer 142, the thermal conductive metal layer 142 is coated on the lower surface 141b of the ceramic powder sintered layer 141 by using a high temperature liquid state material, and partial material of the thermal conductive metal layer 142 fills up the voids 1411 exposed from the lower surface 141b. Under high temperature, the particles between the high temperature liquid state material and the inner wall of the voids 1411 are strongly and chemically bonded to each other, such that after the high temperature liquid state material cools and solidifies, the thermal conductive metal layer 142 and the ceramic powder sintered layer 141 are tightly bonded to each other. The thermal conductive metal layer 142 is formed by a ductile material such as copper, aluminum or a combination thereof such that the ductility and strength of the heat dissipation element 140 can be increased.

The heat dissipation element 140 further comprises a thermal interface layer 143 formed between the heating element 130 and the thermal conductive metal layer 142. The thermal conductive metal layer 142 has a joint surface 142u and a polished surface 142b disposed oppositely to each other. The thermal conductive metal layer 142 is disposed on thermal interface layer 143 by the polished surface 142b. The polished surface 142b provides excellent flatness and/or surface accuracy and is capable of reducing the thermal resistance between the thermal conductive metal layer 142 and the thermal interface layer 143.

The thermal interface layer 143 relates to a thermal conductive double-sided adhesive, a phase changed layer or a thermal conductive pad. The phase changed layer has better thermal conductivity than the air. The phase changed layer has solid state when being exposed at a normal atmospheric temperature but is converted into liquid state when being exposed at a high temperature. The liquid state phase changed layer fills up the micro-pores of the thermal conductive metal layer 142 and replaces the air whose thermal conductivity is poor such that the thermal conductivity between the thermal conductive metal layer 142 and the heating element 130 can be increased. The thermal conductive double-sided adhesive can adhere the thermal conductive metal layer 142 onto the heating element 130. When the thermal interface layer 143 is realized by a thermal conductive pad, the heat dissipation element 140 and the heating element 130 can further be clamped together by a buckle (not illustrated). In another example, the heat dissipation element 140 can do without the thermal interface layer 143.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A heat dissipation element, comprising:
a ceramic powder sintered layer having a plurality of voids; and
a thermal conductive metal layer whose partial material is formed within the voids of the ceramic powder sintered layer.

2. The heat dissipation element according to claim 1, wherein the ceramic powder sintered layer has a lower surface, and the thermal conductive metal layer fills up the voids exposed from the lower surface.

3. The heat dissipation element according to claim 1, wherein the thermal conductive metal layer is formed by a ductile material.

4. The heat dissipation element according to claim 1, wherein the thermal conductive metal layer is formed by copper, aluminum or a combination thereof.

5. The heat dissipation element according to claim 1, wherein the thickness of the ceramic powder sintered layer is larger than the thickness of the thermal conductive metal layer.

6. The heat dissipation element according to claim 5, wherein the thickness of the ceramic powder sintered layer is 5-15 times as much as the thickness of the thermal conductive metal layer.

7. The heat dissipation element according to claim 1, wherein, the thermal conductive metal layer has a joint surface and a polished surface opposite to the joint surface, the thermal conductive metal layer is jointed to the ceramic powder sintered layer by the joint surface and is disposed on a thermal interface layer by the polished surface.

8. The heat dissipation element according to claim 1, wherein, a plurality of particles between the thermal conductive metal layer and the inner wall of the voids are chemically bonded to each other.

9. A communication device, comprising:
a heating element having an upper surface; and
a heat dissipation element disposed on the upper surface of the heating element and comprising:
a ceramic powder sintered layer having a plurality of voids; and
a thermal conductive metal layer whose partial material is formed in the voids of the ceramic powder sintered layer.

10. The communication device according to claim 9, wherein, the heating element relates to a communication chip.

11. The communication device according to claim 9, wherein, the ceramic powder sintered layer has a lower surface, and the thermal conductive metal layer fills up the voids exposed from the lower surface.

12. The communication device according to claim 9, further comprising:
a thermal interface layer formed between the heating element and the thermal conductive metal layer.

13. The communication device according to claim 12, wherein, the thermal interface layer relates to a thermal conductive double-sided adhesive, a phase changed layer or a thermal conductive pad.

14. The communication device according to claim 12, wherein, the thermal conductive metal layer has a joint surface and a polished surface disposed opposite to the joint surface, and the thermal conductive metal layer is jointed to the ceramic powder sintered layer by the joint surface and is disposed on thermal interface layer by the polished surface.

15. The communication device according to claim 9, wherein, the area of the heat dissipation element is at least two times as much as the area of the heating element.

16. The communication device according to claim, further comprising:
a circuit board on which the heating element is disposed.

17. The communication device according to claim 9, wherein, a plurality of particles between the thermal conductive metal layer and the inner wall of the voids are chemically bonded to each other.
